(19) United States
(12) Patent Application Publication
(10) Pub. No.: US 2024/0258274 A1
(43) Pub. Date: Aug. 1, 2024

(54) SEMICONDUCTOR PACKAGES AND METHOD FOR FABRICATING THE SAME

(71) Applicant: SAMSUNG ELECTRONICS CO., LTD., Suwon-si (KR)

(72) Inventors: Sangkyu LEE, Suwon-si (KR); Yi Eok KWON, Suwon-si (KR)

(73) Assignee: SAMSUNG ELECTRONICS CO., LTD., Suwon-si (KR)

(21) Appl. No.: 18/236,673

(22) Filed: Aug. 22, 2023

(30) Foreign Application Priority Data
Jan. 26, 2023 (KR) 10-2023-0010397

(51) Int. Cl. H01L 25/065; H01L 21/56; H01L 23/00; H01L 25/00

(52) U.S. Cl. CPC H01L 25/0657; H01L 21/568; H01L 24/05; H01L 24/08; H01L 24/16; H01L 24/24; H01L 24/73; H01L 25/50; H01L 24/32; H01L 24/48; H01L 2224/0557; H01L 2224/05647; H01L 2224/08145; H01L 2224/16145; H01L 2224/16227; H01L 2224/24227; H01L 2224/244; H01L 2224/32145; H01L 2224/32225; H01L 2224/48091; H01L 2224/48227; H01L 2224/73204; H01L 2224/73253; H01L 2224/73259; H01L 2224/73265; H01L 2224/73267; H01L 2225/0651; H01L 2225/06513; H01L 2225/06517; H01L 2225/06541; H01L 2225/06548

(57) ABSTRACT

Provided is a semiconductor package including a redistribution layer, a three-dimensional integrated circuit (3D IC) structure on the redistribution layer, a plurality of conductive posts on the redistribution layer adjacent to the 3D IC structure, a molding material on the redistribution layer and encapsulating the 3D IC structure and the plurality of conductive posts, and a printed circuit board (PCB) on the molding material.

### CROSS-REFERENCE TO RELATED APPLICATION

This application claims priority to Korean Patent Application No. 10-2023-0010397 filed in the Korean Intellectual Property Office on Jan. 26, 2023, the entirety of which is incorporated herein by reference.

### BACKGROUND

### 1. Field

Embodiments of the present disclosure relate to semiconductor packages and a method for fabricating the same.

### 2. Description of Related Art

The semiconductor industry has been seeking to improve integration density such that more passive or active devices can be integrated in a given area. However, in the process, the development of technology for dramatically reducing circuit line widths in the semiconductor front-end process has gradually faced limitations. For this reason, the semiconductor industry has been developing semiconductor packaging technologies capable of realizing high integration density to supplement the limitations of the semiconductor front-end process. As one of the semiconductor packaging technologies developed depending on this tendency, package-on-package (POP) for stacking an upper semiconductor package on top of a lower semiconductor package is well known.

The existing package-on-package (POP) technology is completed through a process of forming a lower semiconductor package by mounting a semiconductor chip on a front side redistribution layer (FRDL) and encapsulating the semiconductor chip (for example, a system-on-chip (SOC)) with a molding material, and forming a back side redistribution layer (BRDL) on the lower semiconductor package, and connecting an upper semiconductor package (for example, a memory package) to the upper part of the lower semiconductor package through the back side redistribution layer (BRDL).

A system-on-chip (SOC) which is included in a lower semiconductor package of the package-on-package (POP) technology is one semiconductor chip having individual semiconductors, such as microprocessors, memory semiconductors, digital signal processing chips, and wireless modems, integrated therein. Since a number of functions are integrated in one semiconductor chip to drive all of the applications and control and manage system devices, a number of interface devices, and so on, if a system-on-chip (SOC) is used, it is possible to reduce the size of a semiconductor package and minimize power which is consumed in the semiconductor package, as compared to when the existing individual semiconductors are used.

However, in the case where individual semiconductors in a system-on-chip (SOC) include any defective semiconductors manufactured at a low manufacturing cost by a relatively old process (for example, a wireless modem), semiconductors manufactured at a high manufacturing cost by a new process (for example, microprocessors and memory semiconductors) must also be discarded together. Therefore, if system-on-chips (SOCs) can be manufactured in a multi-die structure by distinguishing them, the yield of system-on-chips (SOCs) can increase.

The package-on-package (POP) technology involves a number of processes and has the disadvantage of high manufacturing costs because fine patterning processes are repeatedly performed to form front side redistribution layers (FRDLs) and back side redistribution layers (BRDLs). Therefore, in the package-on-package (POP) technology, when back side redistribution layers (BRDLs) are replaced with other structures, it is possible to reduce the number of processes and reduce the manufacturing costs.

Therefore, it is required to develop a new semiconductor packaging technology capable of solving the problems of the existing package-on-package (POP) technology.

### SUMMARY

One or more example embodiments provide a semiconductor package and a method for fabricating the semiconductor package having advantages of being able to implement a system-on-chip (SOC) as a three-dimensional integrated circuit (3D IC) structure by distinguishing individual semiconductors to be included in a system-on-chip (SOC) included in the package-on-package (POP) technology under a predetermined criterion, and stacking each of the individual semiconductors on a front side redistribution layer (FRDL) in a package-on-package (POP) fabricating process.

One or more example embodiments also provide a semiconductor package and a method for fabricating the semiconductor package having advantages of replacing a back side redistribution layer (BRDL) of the package-on-package (POP) technology with a back side printed circuit board (PCB).

According to an aspect of an example embodiment, there is provided a semiconductor package including a redistribution layer, a three-dimensional integrated circuit (3D IC) structure on the redistribution layer, a plurality of conductive posts on the redistribution layer adjacent to the 3D IC structure, a molding material on the redistribution layer and encapsulating the 3D IC structure and the plurality of conductive posts, and a printed circuit board (PCB) on the molding material.

According to another aspect of an example embodiment, there is provided a semiconductor package including a redistribution layer, a three-dimensional integrated circuit (3D IC) structure on the redistribution layer, the 3D IC structure including a first semiconductor chip die and a second semiconductor chip die below the first semiconductor chip die, a plurality of conductive posts on the redistribution layer adjacent to the 3D IC structure, a molding material on the redistribution layer and encapsulating the 3D IC structure and the plurality of conductive posts, a printed circuit board (PCB) on the molding material, and a third semiconductor chip die on the PCB, wherein a lower surface of each conductive post of the plurality of conductive posts is on the redistribution layer and an upper surface of each conductive post of the plurality of conductive posts is below the PCB, and wherein a die attach film (DAF) is between an upper surface of the first semiconductor chip die and the PCB and conductive connection members are between a lower surface of the second semiconductor chip die and the redistribution layer.

According to another aspect of an example embodiment, there is provided A method for fabricating a semiconductor package, including forming a plurality of conductive posts on a printed circuit board (PCB), forming a three-dimensional integrated circuit (3D IC) structure on the PCB, encapsulating the plurality of conductive posts and the 3D IC structure with a molding material, forming a front side redistribution layer on the molding material, and forming external connection terminals on the front side redistribution layer.

### BRIEF DESCRIPTION OF DRAWINGS

The above and other aspects, features, and advantages of the embodiments will be more clearly understood from the following detailed description, taken in conjunction with the accompanying drawings, in which:

FIG. 1 is a cross-sectional view illustrating a semiconductor package of an example embodiment including a 3D IC structure manufactured by sequentially stacking semiconductor chip dies in the process of fabricating the semiconductor package;

FIG. 2 is a cross-sectional view illustrating a semiconductor package of an example embodiment including a 3D IC structure manufactured in a separate process that is not included in the process of fabricating the semiconductor package;

FIG. 3 is a cross-sectional view illustrating a semiconductor package of an example embodiment including a 3D IC structure manufactured by bonding a first semiconductor chip die and a second semiconductor chip die by hybrid bonding;

FIG. 4 is a cross-sectional view illustrating a step of providing a back side printed circuit board (PCB) as one step of a series of steps of a method for fabricating a semiconductor package;

FIG. 5 is a cross-sectional view illustrating a step of bonding the back side printed circuit board (PCB) to a carrier, as one step of the series of steps of the method for fabricating the semiconductor package;

FIG. 6 is a cross-sectional view illustrating a step of forming conductive posts on the back side printed circuit board (PCB), as one step of the series of steps of the method for fabricating the semiconductor package;

FIG. 7A is a cross-sectional view illustrating a step of bonding a first semiconductor chip die on the back side printed circuit board (PCB), as one step of the series of steps of the method for fabricating the semiconductor package;

FIG. 7B is a cross-sectional view illustrating a step of bonding a 3D IC structure, manufactured in advance in a separate process, on the back side printed circuit board (PCB), as one step of the series of steps of the method for fabricating the semiconductor package;

FIG. 8A is a cross-sectional view illustrating a step of bonding a second semiconductor chip die on the first semiconductor chip die using micro bumps, following the step of FIG. 7A, as one step of the series of steps of the method for fabricating the semiconductor package;

FIG. 8B is a cross-sectional view illustrating a step of bonding a second semiconductor chip die on the first semiconductor chip die by hybrid bonding, following the step of FIG. 7A, as one step of the series of steps of the method for fabricating the semiconductor package;

FIG. 9 is a cross-sectional view illustrating a step of encapsulating the 3D IC structure and the conductive posts, as one step of the series of steps of the method for fabricating the semiconductor package;

FIG. 10 is a cross-sectional view illustrating a step of planarizing the upper surfaces of the conductive posts and the upper surface of the molding material, as one step of the series of steps of the method for fabricating the semiconductor package;

FIG. 11 is a cross-sectional view illustrating a step of forming a front side redistribution layer on the molding material, as one step of the series of steps of the method for fabricating the semiconductor package;

FIG. 12 is a cross-sectional view illustrating a step of forming external connection members on the front side redistribution layer, as one step of the series of steps of the method for fabricating the semiconductor package;

FIG. 13 is a cross-sectional view illustrating a step of debonding the carrier from the back side printed circuit board (PCB), as one step of the series of steps of the method for fabricating the semiconductor package;

FIG. 14 is a cross-sectional view illustrating a step of bonding a semiconductor chip on the semiconductor package by flip-chip bonding, as one step of the series of steps of the method for fabricating the semiconductor package; and

FIG. 15 is a cross-sectional view illustrating a step of bonding a semiconductor chip on the semiconductor package by wire bonding, as one step of the series of steps of the method for fabricating the semiconductor package.

### DETAILED DESCRIPTION

In the following detailed description, only certain example embodiments of the present invention have been shown and described, simply by way of illustration. The present invention can be variously implemented and is not limited to the following example embodiments.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present invention is not limited thereto.

Throughout this specification, when a part is referred to as being “connected” to another part, it may be directly connected to the other part, or may be connected to the other part indirectly with any other elements interposed therebetween. In addition, unless explicitly described to the contrary, the word “comprise”, and variations such as “comprises” or “comprising”, will be understood to imply the inclusion of stated elements but not the exclusion of any other elements.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “above” or “on” a reference portion, the element is located above or below the reference portion, and it does not necessarily mean that the element is located “above” or “on” in a direction opposite to gravity.

Further, in the entire specification, when it is referred to as “on a plane”, it means when a target part is viewed from above, and when it is referred to as “on a cross-section”, it means when the cross-section obtained by cutting a target part vertically is viewed from the side.

Hereinafter, a semiconductor package and a method for fabricating the semiconductor package according to an example embodiment will be described with reference to the drawings.

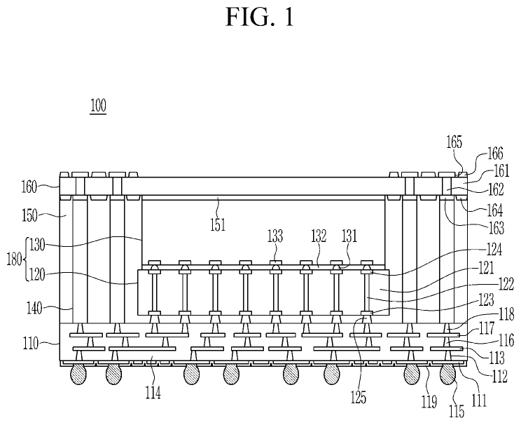

FIG. 1 is a cross-sectional view illustrating a semiconductor package 100 of an example embodiment including a 3D IC structure 180 manufactured by sequentially stacking semiconductor chip dies in the process of fabricating the semiconductor package 100.

Referring to FIG. 1, the semiconductor package 100 may include a front side redistribution layer 110, the 3D IC structure 180 including a first semiconductor chip die 130 and a second semiconductor chip die 120, conductive posts 140, a molding material 150, a back side printed circuit board (PCB) 160, and external connection members 115.

The front side redistribution layer 110 may include a dielectric layer 114, and first redistribution vias 112, first redistribution lines 113, second redistribution vias 116, second redistribution lines 117, and third redistribution via 118 formed in the dielectric layer 114. In another example embodiment, a redistribution layer may have fewer or more redistribution lines and redistribution vias.

The first redistribution vias 112 are disposed between the first redistribution lines 113 and bonding pads 111. The first redistribution vias 112 electrically couple the first redistribution lines 113 with the external connection members 115 passing through the bonding pads 111 in the vertical direction. The first redistribution lines 113 are disposed between the first redistribution vias 112 and the second redistribution vias 116. The first redistribution lines 113 electrically couple the first redistribution vias 112 with the second redistribution vias 116 in the horizontal direction. The second redistribution vias 116 are disposed between the first redistribution lines 113 and the second redistribution lines 117. The second redistribution vias 116 electrically couple the first redistribution lines 113 with the second redistribution lines 117 in the vertical direction. The second redistribution lines 117 are disposed between the second redistribution vias 116 and the third redistribution vias 118. The second redistribution lines 117 electrically couple the second redistribution vias 116 with the third redistribution vias 118 in the horizontal direction. The third redistribution vias 118 are disposed between the second redistribution lines 117 and the plurality of conductive posts 140. The third redistribution vias 118 electrically couple the second redistribution lines 117 with the plurality of conductive posts 140 in the vertical direction.

The 3D IC structure 180 may include the first semiconductor chip die 130 and the second semiconductor chip die 120. A 3D IC may be an integrated circuit implemented as a single three-dimensional chip by a technique of stacking circuits in the vertical direction, not by the related technique of arranging circuits in the horizontal direction. When the vertical stacking technique is used, it is possible to implement more elements in the same silicon wafer area. Therefore, it becomes possible to reduce the manufacturing cost and improve the performance.

The second semiconductor chip die 120 may include second semiconductor chips 121, through-silicon vias (TSVs) 122, lower bonding pads 123, upper bonding pads 124, and connection terminals 125. In an example embodiment, the second semiconductor chips 121 may include a central processing unit (CPU) or a graphic processing unit (GPU). The through-silicon vias (TSVs) 122 are disposed between the lower bonding pads 123 and the upper bonding pads 124. The through-silicon vias (TSVs) 122 electrically couple the lower bonding pads 123 with the upper bonding pads 124.

In the 3D IC structure 180, the first semiconductor chip die 130 is disposed to be spaced apart from the front side redistribution layer 110 which transmits signals and power. For this reason, the through-silicon vias (TSVs) 122 are disposed between the second semiconductor chips 121 of the second semiconductor chip die 120 and are connected to the first semiconductor chip die 130 to increase the speed in receiving and responding signals and power of the first semiconductor chip die 130.

The lower bonding pads 123 are disposed between the through-silicon vias (TSVs) 122 and the connection terminals 125, and electrically couple the through-silicon vias (TSVs) 122 with the connection terminals 125. The upper bonding pads 124 are disposed between the through-silicon vias (TSVs) 122 and the connection members 131. The upper bonding pads 124 electrically couple the through-silicon vias (TSVs) 122 with the first semiconductor chip die 130 connected to the connection members 131. The connection terminals 125 are disposed between the lower bonding pads 123 and the front side redistribution layer 110. The connection terminals 125 electrically couple the lower bonding pads 123 with the front side redistribution layer 110. In an example embodiment, the diameter or width of the horizontal cross sections of the connection terminals 125 may be 10 μm to 300 μm in consideration of alignments allowable during exposure.

The first semiconductor chip die 130 may include first semiconductor chips and bonding pads 133. In an example embodiment, the first semiconductor chips may include a wireless modem. The first semiconductor chip die 130 is bonded to the back side printed circuit board (PCB) 160 by a die attach film (DAF) 151. The bonding pads 133 are bonded to the connection members 131 to be electrically coupled with them. In an example embodiment, the connection members 131 may include micro bumps. An insulating member 132 surrounds the connection members 131 between the first semiconductor chip die 130 and the second semiconductor chip die 120. In an example embodiment, the insulating member 132 may include an underfill material.

The conductive posts 140 are disposed between the front side redistribution layer 110 and the back side printed circuit board (PCB) 160, and electrically couple the front side redistribution layer 110 with the back side printed circuit board (PCB) 160. In an example embodiment, the diameter or width of the horizontal cross sections of the conductive posts 140 may be 10 μm or 300 μm.

The molding material 150 encapsulates the first semiconductor chip die 130, the second semiconductor chip die 120, and the conductive posts 140 on the front side redistribution layer 110. For example, the molding material 150 covers the side surface of the first semiconductor chip die 130, the side surface and the lower surface of the second semiconductor chip die 120, the side surfaces of the conductive posts 140, and the side surfaces of the connection terminals 125 on the front side redistribution layer 110. Since the first semiconductor chip die 130 is directly bonded to the back side printed circuit board (PCB) 160 by the die attach film (DAF) 151, the molding material 150 does not cover and exposes the upper surface of the first semiconductor chip die 130.

The back side printed circuit board (PCB) 160 may include a core layer 161, vias 162, first bonding pads 163, a first insulating layer 164, second bonding pads 165, and a second insulating layer 166. The back side printed circuit board (PCB) 160 is bonded to the first semiconductor chip die 130 by the die attach film (DAF) 151. In an example embodiment, the die attach film (DAF) 151 may be bonded to the core layer 161 of the back side printed circuit board (PCB) 160. In another example embodiment, the die attach film (DAF) 151 may be bonded to the first insulating layer 164 of the back side printed circuit board (PCB) 160. In an example embodiment, the thickness of the die attach film (DAF) 151 may be greater than or equal to 5 μm. In another example embodiment, the thickness of the die attach film (DAF) 151 may be 5 μm to 40 μm.

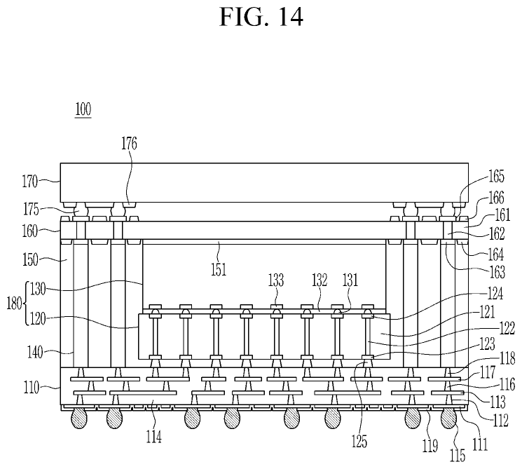

The core layer 161 is located at the center of the back side printed circuit board (PCB) 160 in the vertical direction. The vias 162 are disposed between the first bonding pads 163 and the second bonding pads 165. The vias 162 electrically couple a third semiconductor chip die 170 (see FIG. 14) connected to the second bonding pads 165 with the conductive posts 140 connected to the first bonding pads 163.

The first bonding pads 163 are disposed between the conductive posts 140 and the vias 162. The first bonding pads 163 electrically couple the conductive posts 140 with the vias 162. The first insulating layer 164 may have a plurality of openings for soldering. The first insulating layer 164 prevents the first bonding pad 163 from being short-circuited.

The second bonding pads 165 are disposed between the third semiconductor chip die 170 (see FIG. 14) and the vias 162. The second bonding pads 165 electrically couple the third semiconductor chip die 170 (see FIG. 14) with the vias 162. The second insulating layer 166 may have a plurality of openings for soldering. The second insulating layer 166 prevents the second bonding pads 165 from being short-circuited.

The back side printed circuit board (PCB) 160 that does not require fine patterning processes to be performed may substitute for a back side redistribution layer (BRDL) that requires fine patterning processes to be performed in package-on-package (POP). Therefore, the semiconductor package 100 of the package-on-package (POP) according to the example embodiment includes the front side redistribution layer 110 at the lower part, and includes the back side printed circuit board (PCB) 160 at the upper part. Accordingly, it is possible to reduce the number of redistribution processes and reduce the manufacturing cost.

The front side redistribution layer 110 and the back side printed circuit board (PCB) 160 of the semiconductor package 100 are made of different materials. In an example embodiment, the front side redistribution layer 110 may include a photosensitive polymer layer. Photosensitive polymers are materials applicable to a photolithography process to form fine patterns. In an example embodiment, the front side redistribution layer 110 may include photoimageable dielectric (PID) (a photosensitive dielectric) which is used in a redistribution process. As an example embodiment, the photoimageable dielectric (PID) may include a polyimide-based photosensitive polymer, a novolac-based photosensitive polymer, polybenzoxazole, a silicon-based polymer, an acrylate-based polymer, or an epoxy-based polymer. In an example embodiment, the photoimageable dielectric (PID) may have a resolution of 3 μm. In an example embodiment, the back side printed circuit board (PCB) 160 may include FR-4. In an example embodiment, the back side printed circuit board (PCB) 160 may include epoxy and glass fibers.

The photoimageable dielectric (PID) has a coefficient of thermal expansion (CTE) of about 40 ppm/° C. to 60 ppm/° C., and has a modulus of elasticity of about 500 Mpa to 5.0 Gpa. The FR-4 has a coefficient of thermal expansion (CTE) of about 5 ppm/° C. to 20 ppm/° C., and has a modulus of elasticity of about 50 Gpa to 150 Gpa. The coefficient of thermal expansion (CTE) of the front side redistribution layer 110 including the photoimageable dielectric (PID) is greater than the coefficient of thermal expansion of the back side printed circuit board (PCB) 160 including the FR-4, and the modulus of elasticity of the back side printed circuit board (PCB) 160 including the RF-4 is greater than the modulus of elasticity of the front side redistribution layer 110 including the photoimageable dielectric (PID).

Due to this feature, the semiconductor package 100 including the back side printed circuit board (PCB) 160 may have an enhanced strength of 67N, and is more resistant to warpage, and has higher reliability, as compared to a semiconductor package including a back side redistribution layer and having a strength of 53N.

The external connection members 115 electrically couple an external component with the front side redistribution layer 110 connected to the bonding pads 111 disposed beneath the front side redistribution layer 110. An insulating layer 119 may have a plurality of openings for soldering. In an example embodiment, the insulating layer 119 may include solder resist. The insulating layer 119 prevents the external connection members 115 from being short-circuited.

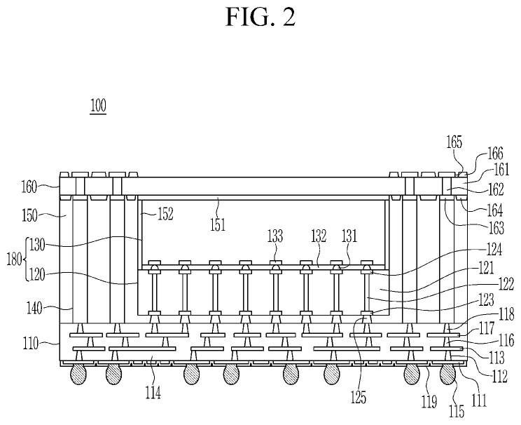

FIG. 2 is a cross-sectional view illustrating a semiconductor package 100 of an example embodiment including a 3D IC structure 180 manufactured in a separate process that is not included in the process of fabricating the semiconductor package 100.

Referring to FIG. 2, the semiconductor package 100 may include the 3D IC structure 180 fabricated in advance. Since the 3D IC structure 180 is fabricated by performing the separate process, a second molding material 152 is further included in the 3D IC structure 180. The second molding material 152 encapsulates a first semiconductor chip die 130 on a second semiconductor chip die 120. The second molding material 152 may be between the first semiconductor chip die 130 and the molding material 150. In an example embodiment, the second molding material 152 may be a different type of molding material from the molding material 150. In another example embodiment, the second molding material 152 may be the same type of molding material as the molding material 150.

The features of the configuration of the semiconductor package 100 of FIG. 1 described above may be applied to the configuration of the semiconductor package 100 of FIG. 2 except that the 3D IC structure 180 further includes the second molding material 152.

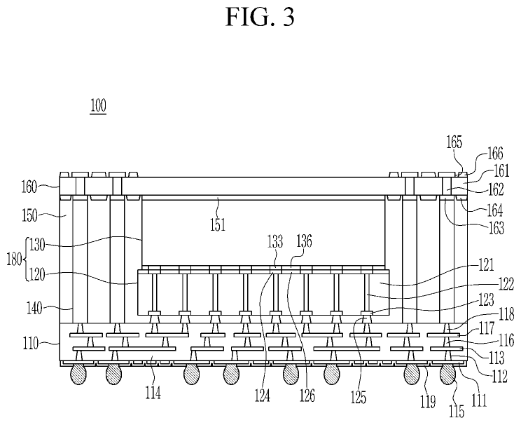

FIG. 3 is a cross-sectional view illustrating a semiconductor package 100 of an example embodiment including a 3D IC structure 180 manufactured by bonding a first semiconductor chip die 130 and a second semiconductor chip die 120 by hybrid bonding.

Referring to FIG. 3, the semiconductor package 100 may include the 3D IC structure 180 made by bonding the first semiconductor chip die 130 and the second semiconductor chip die 120 by hybrid bonding. The first semiconductor chip die 130 may include bonding pads 133 and a silicon insulating layer 136 provided on the lower surface of the first semiconductor chip die 130. The silicon insulating layer 136 may be provided adjacent to the boding pads 133. The second semiconductor chip die 120 may include bonding pads 124 and a silicon insulating layer 126 provided on the upper surface of the second semiconductor chip die 120. The silicon insulating layer 126 may be provided adjacent to the bonding pads 124. The bonding pads 133 of the first semiconductor chip die 130 are directly bonded to the bonding pads 124 of the second semiconductor chip die 120 by metal-to-metal bonding of hybrid bonding, and the silicon insulating layer 136 of the first semiconductor chip die 130 is directly bonded to the silicon insulating layer 126 of the second semiconductor chip die 120 by nonmetal-to-nonmetal bonding of the hybrid bonding.

In an example embodiment, the bonding pads 133 of the first semiconductor chip die 130 and the bonding pads 124 of the second semiconductor chip die 120 may include copper (Cu). In another example embodiment, the bonding pads 133 of the first semiconductor chip die 130 and the bonding pads 124 of the second semiconductor chip die 120 may be a metallic material to which hybrid bonding can be applied. In an example embodiment, the silicon insulating layer 136 of the first semiconductor chip die 130 and the silicon insulating layer 126 of the second semiconductor chip die 120 may include silicon oxide. In an example embodiment, the silicon insulating layer 136 of the first semiconductor chip die 130 and the silicon insulating layer 126 of the second semiconductor chip die 120 may include SiO₂. In another example embodiment, the silicon insulating layer 136 of the first semiconductor chip die 130 and the silicon insulating layer 126 of the second semiconductor chip die 120 may be silicon nitride, silicon oxynitride, or other suitable dielectric materials.

The features of the configuration of the semiconductor package 100 of FIG. 1 described above may be applied to the configuration of the semiconductor package 100 of FIG. 3 except that the first semiconductor chip die 130 and the second semiconductor chip die 120 are bonded by hybrid bonding.

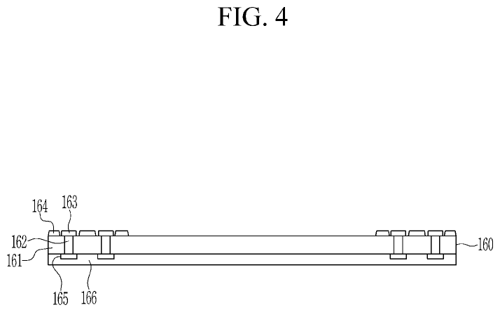

FIG. 4 is a cross-sectional view illustrating a step of providing the back side printed circuit board (PCB) 160 as one step of a series of steps of a method for fabricating a semiconductor package.

Referring to FIG. 4, the back side printed circuit board (PCB) 160 may include the core layer 161, vias 162, the first bonding pads 163, the first insulating layer 164, the second bonding pads 165, and the second insulating layer 166.

The core layer 161 has a relatively high mechanical strength against warpage or physical impact and may prevent deformation of the back side printed circuit board (PCB) 160. In an example embodiment, the core layer 161 may include FR-4. In an example embodiment, the core layer 161 may include prepreg. In an example embodiment, the core layer 161 may include epoxy and glass fibers.

The vias 162 are formed to penetrate the core layer 161. In an example embodiment, the vias 162 may have a cylindrical shape or a through-hole shape. In an example embodiment, the vias 162 may have inclined sides. In an example embodiment, the vias 162 may include at least one of copper, aluminum, tungsten, nickel, gold, tin, titanium, and alloys thereof.

The first bonding pads 163 are disposed on one surface of the core layer 161, and are bonded to ends of the vias 162. The second bonding pads 165 are disposed on the other surface of the core layer 161, and are bonded to the other ends of the vias 162. The first bonding pads 163 and the second bonding pads 165 may include at least one of copper, nickel, zinc, gold, silver, platinum, palladium, chromium, titanium, and alloys thereof.

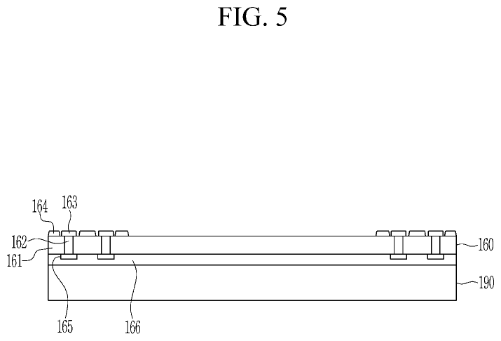

The first insulating layer 164 is disposed to surround the individual first bonding pads 163 in order to prevent short-circuiting of the first bonding pads 163. The second insulating layer 166 fully covers the second bonding pads 165 such that the second bonding pads 165 are not exposed and a carrier 190 (see FIG. 5) can be attached to the second insulating layer 166. In an example embodiment, the first insulating layer 164 and the second insulating layer 166 may include solder resist.

FIG. 5 is a cross-sectional view illustrating a step of bonding the back side printed circuit board (PCB) 160 to the carrier 190, as one step of the series of steps of the method for fabricating the semiconductor package.

Referring to FIG. 5, the carrier 190 is attached to the front side redistribution layer 110. The carrier 190 may include, for example, a silicon-based material such as glass or silicon oxide, an organic material, other materials such as aluminum oxide, an arbitrary combination thereof, or the like.

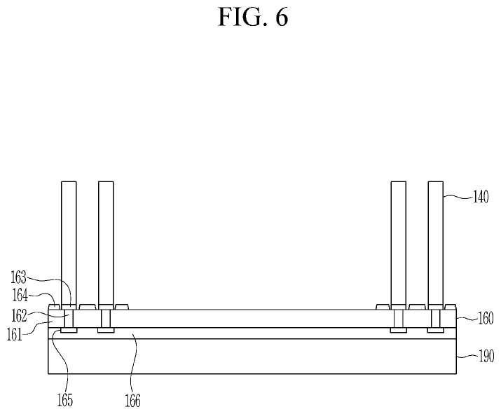

FIG. 6 is a cross-sectional view illustrating a step of forming the conductive posts 140 on the back side printed circuit board (PCB) 160, as one step of the series of steps of the method for fabricating the semiconductor package.

Referring to FIG. 6, the conductive posts 140 are bonded to the first bonding pads 163 of the back side printed circuit board (PCB) 160 to extend in the vertical direction. In an example embodiment, the conductive posts 140 may be formed by performing a sputtering process. In another example embodiment, the conductive posts 140 may be formed by forming a metal seed layer and then performing an electroplating process. In an example embodiment, the conductive posts 140 may be at least one of copper, nickel, gold, silver, aluminum, tungsten, titanium, tantalum, indium, molybdenum, manganese, cobalt, tin, magnesium, rhenium, beryllium, gallium, ruthenium, and alloys thereof.

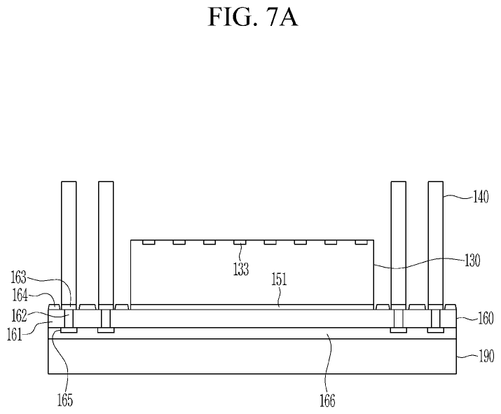

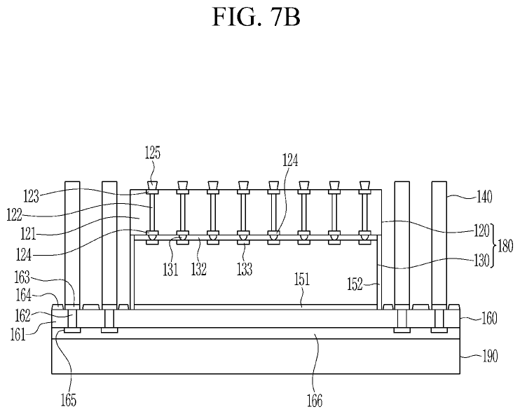

FIG. 7A is a cross-sectional view illustrating a step of bonding the first semiconductor chip die 130 on the back side printed circuit board (PCB) 160, as one step of the series of steps of the method for fabricating the semiconductor package.

Referring to FIG. 7A, the first semiconductor chip die 130 is bonded to the back side printed circuit board (PCB) 160 by the die attach film (DAF) 151. In the step of forming a system-on-chip (SOC) with the 3D IC structure 180, the first semiconductor chip die 130 is bonded to the back side printed circuit board (PCB) 160 with the die attach film (DAF), whereby it is possible to reduce the manufacturing cost.

Since a system-on-chip (SOC) to be included in a package-on-package (POP) is fabricated in the process of fabricating the package-on-package (POP), a separate process for fabricating the system-on-chip (SOC) is unnecessary. Therefore, it is possible to reduce use of a molding material (EMC) which is essentially used when a system-on-chip (SOC) is fabricated in a separate process.

FIG. 7B is a cross-sectional view illustrating a step of bonding a 3D IC structure 180, manufactured in advance in a separate process, on the back side printed circuit board (PCB) 160, as one step of the series of steps of the method for fabricating the semiconductor package.

Referring to FIG. 7B, the 3D IC structure 180 manufactured in advance is bonded to the back side printed circuit board (PCB) 160 by the die attach film (DAF) 151. Unlike the example embodiment shown in FIG. 7A, since the 3D IC structure 180 is manufactured by performing a separate process, the 3D IC structure 180 includes a second molding material 152 encapsulating the first semiconductor chip die 130 on the second semiconductor chip die 120.

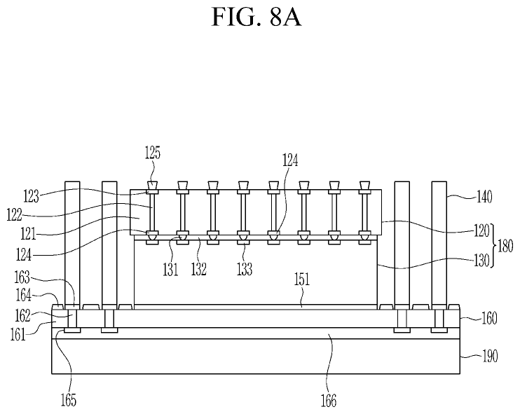

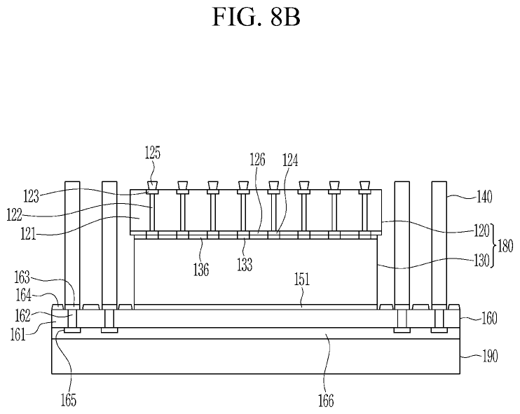

FIG. 8A is a cross-sectional view illustrating a step of bonding the second semiconductor chip die 120 to the upper surface of the first semiconductor chip die 130 using micro bumps 131, following the step of FIG. 7A, as one step of the series of steps of the method for fabricating the semiconductor package.

Referring to FIG. 8A, the second semiconductor chip die 120 is bonded on the first semiconductor chip die 130. The bonding pads 133 of the first semiconductor chip die 130 and the bonding pads 124 of the second semiconductor chip die 120 may be bonded using the connection members 131.

Through this step of performing bonding using the micro bumps 131, the first semiconductor chip die 130 is vertically stacked on the second semiconductor chip die 120, and in the process of forming a package-on-package (POP), a system-on-chip (SOC) including the first semiconductor chip die 130 and the second semiconductor chip die 120 is formed as the 3D IC structure 180.

FIG. 8B is a cross-sectional view illustrating a step of bonding the second semiconductor chip die 120 on the first semiconductor chip die 130 by hybrid bonding, following the step of FIG. 7A, as one step of the series of steps of the method for fabricating the semiconductor package.

Referring to FIG. 8B, the second semiconductor chip die 120 is bonded on the first semiconductor chip die 130 by hybrid bonding. Hybrid bonding is bonding two devices by a method of fusing the same material of the two devices using the bonding property of the same material. Here, the hybrid bonding means performing two different types of bonding, for example, bonding two devices by a first type of metal-to-metal bonding and a second type of nonmetal-to-nonmetal bonding.

The bonding pads 133 of the first semiconductor chip die 130 and the bonding pads 124 of the second semiconductor chip die 120 may be directly bonded by metal-to-metal bonding of the hybrid bonding. By the metal-to-metal bonding of the hybrid bonding, metallic bonds are formed at the interfaces between the bonding pads 133 of the first semiconductor chip die 130 and the bonding pads 124 of the second semiconductor chip die 120. The bonding pads 133 of the first semiconductor chip die 130 and the bonding pads 124 of the second semiconductor chip die 120 may be formed of the same material such that after hybrid bonding, the interfaces between the bonding pads 133 of the first semiconductor chip die 130 and the bonding pads 124 of the second semiconductor chip die 120 may disappear. Through the bonding pads 133 of the first semiconductor chip die 130 and the bonding pads 124 of the second semiconductor chip die 120, the first semiconductor chip die 130 and the second semiconductor chip die 120 can be electrically connected to each other.

The silicon insulating layer 136 of the first semiconductor chip die 130 may be directly bonded to the silicon insulating layer 126 of the second semiconductor chip die 120 by nonmetal-to-nonmetal bonding of the hybrid bonding. By the nonmetal-to-nonmetal bonding of the hybrid bonding, a covalent bond is formed at the interface between the silicon insulating layer 136 of the first semiconductor chip die 130 and the silicon insulating layer 126 of the second semiconductor chip die 120. The silicon insulating layer 136 of the first semiconductor chip die 130 and the silicon insulating layer 126 of the second semiconductor chip die 120 may be formed of the same material such that after hybrid bonding, the interface between the silicon insulating layer 136 of the first semiconductor chip die 130 and the silicon insulating layer 126 of the second semiconductor chip die 120 may disappears.

Through this bonding step using hybrid bonding, the first semiconductor chip die 130 is vertically stacked on the second semiconductor chip die 120, and in the process of forming a package-on-package (POP), a system-on-chip (SOC) including the first semiconductor chip die 130 and the second semiconductor chip die 120 is formed as the 3D IC structure 180.

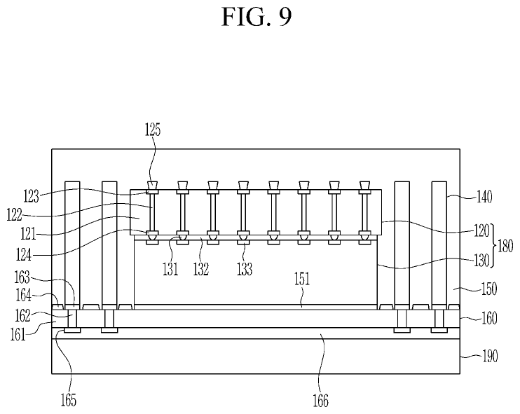

FIG. 9 is a cross-sectional view illustrating a step of encapsulating the 3D IC structure 180 and the conductive posts 140 with the molding material, as one step of the series of steps of the method for fabricating the semiconductor package.

Referring to FIG. 9, the 3D IC structure 180 and the conductive posts 140 are encapsulated on the back side printed circuit board (PCB) 160 with the molding material 150. In some example embodiments, the process of performing encapsulating with the molding material 150 may include a compression molding or transfer molding process. In an example embodiment, the molding material 150 may be made of a thermosetting resin such as an epoxy resin. In another example embodiment, the molding material 150 may be an epoxy molding compound (EMC).

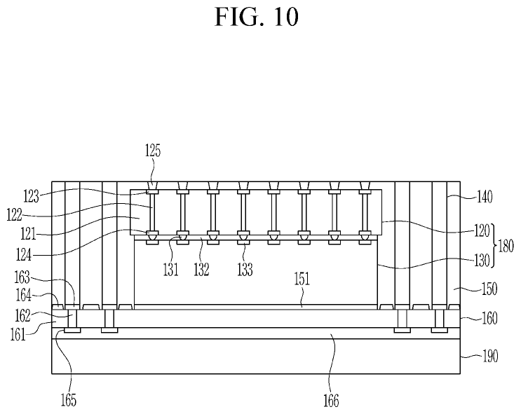

FIG. 10 is a cross-sectional view illustrating a step of planarizing the upper surfaces of the conductive posts 140 and the upper surface of the molding material 150, as one step of the series of steps of the method for fabricating the semiconductor package.

Referring to FIG. 10, chemical mechanical polishing (CMP) is performed to level the upper surfaces of the conductive posts 140 and the upper surface of the molding material 150. The CMP process or a mechanical grinding process is applied to expose the upper surfaces of the conductive posts 140 and planarize the upper surfaces of the conductive posts 140 and the molding material 150.

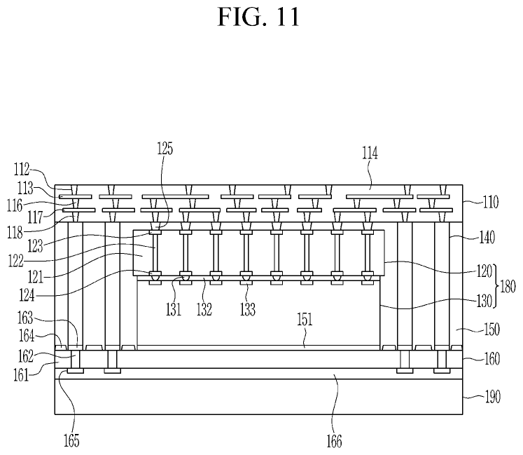

FIG. 11 is a cross-sectional view illustrating a step of forming the front side redistribution layer 110 on the molding material 150, as one step of the series of steps of the method for fabricating the semiconductor package.

On the molding material 150, a dielectric layer 114 is formed. In an example embodiment, the dielectric layer 114 is formed of a polymer such as PBO or polyimide. In another example embodiment, the dielectric layer 114 is formed of an inorganic dielectric material such as silicon nitride or silicon oxide. In an example embodiment, the dielectric layer 114 may be formed by a chemical vapor deposition (CVD), atomic layer deposition (ALD), or plasma enhanced chemical vapor deposition (PECVD) process.

The third redistribution vias 118 are formed by selectively etching the dielectric layer 114 to form via holes and filling the via holes with a conductive material. The third redistribution vias 118 are bonded to the connection terminals 125 of the 3D IC structure 180 or the conductive posts 140.

On the third redistribution vias 118 and the dielectric layer 114, a dielectric layer 114 is further deposited, and the second redistribution lines 117 are formed by selectively etching the additional deposited dielectric layer 114 to form openings and filling the openings with a conductive material.

On the second redistribution lines 117 and the dielectric layer 114, a dielectric layer 114 is further deposited, and the second redistribution vias 116 are formed by selectively etching the additional deposited dielectric layer 114 to form via holes and filling the via holes with a conductive material.

On the second redistribution vias 116 and the dielectric layer 114, a dielectric layer 114 is further deposited, and the first redistribution lines 113 are formed by selectively etching the additional deposited dielectric layer 114 to form openings and filling the openings with a conductive material.

On the first redistribution lines 113 and the dielectric layer 114, a dielectric layer 114 is further deposited, and the first redistribution vias 112 are formed by selectively etching the additional deposited dielectric layer 114 to form via holes and filling the via holes with a conductive material.

In an example embodiment, the first redistribution vias 112, the first redistribution lines 113, the second redistribution vias 116, the second redistribution lines 117, and the third redistribution vias 118 may include at least one of copper, aluminum, tungsten, nickel, gold, tin, titanium, and alloys thereof. In an example embodiment, the first redistribution vias 112, the first redistribution lines 113, the second redistribution vias 116, the second redistribution lines 117, and the third redistribution vias 118 may be formed by performing sputtering processes. In another example embodiment, the first redistribution vias 112, the first redistribution lines 113, the second redistribution vias 116, the second redistribution lines 117, and the third redistribution vias 118 may be formed by forming a seed metal layer and then performing an electroplating process.

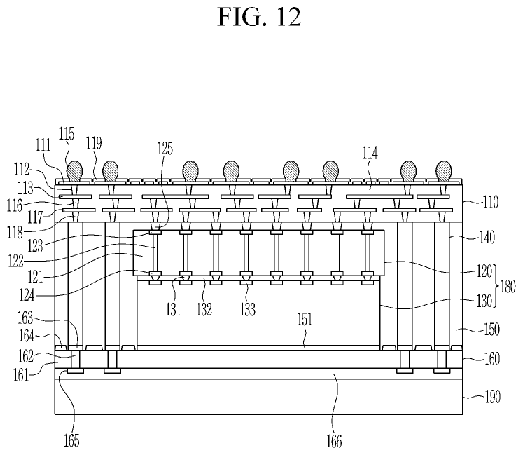

FIG. 12 is a cross-sectional view illustrating a step of forming the external connection members 115 on the front side redistribution layer 110, as one step of the series of steps of the method for fabricating the semiconductor package.

Referring to FIG. 12, the insulating layer 119 may be formed on the dielectric layer 114 of the front side redistribution layer 110, and the bonding pads 111 may be formed on the first redistribution vias 112. In an example embodiment, the insulating layer 119 may be solder resist. The insulating layer 119 may have a plurality of openings for soldering of the external connection members 115 and the bonding pads 111. In an example embodiment, the bonding pads 111 may include at least one of copper, nickel, zinc, gold, silver, platinum, palladium, chromium, titanium, and alloys thereof. In an example embodiment, the external connection members 115 may include at least one of tin, silver, lead, nickel, copper, or alloys thereof.

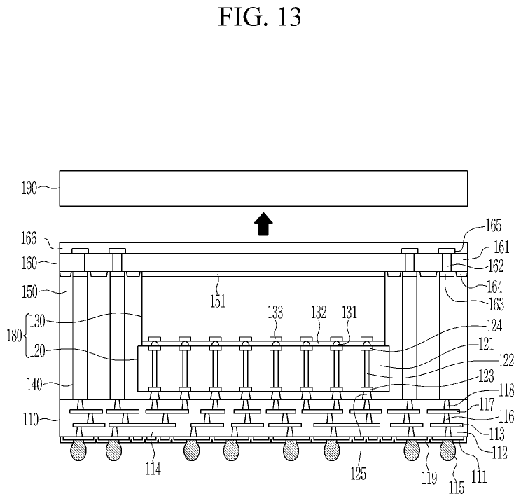

FIG. 13 is a cross-sectional view illustrating a step of debonding the carrier 190 from the back side printed circuit board (PCB), as one step of the series of steps of the method for fabricating the semiconductor package.

Referring to FIG. 13, the carrier 190 is debonded from the back side printed circuit board (PCB).

FIG. 14 is a cross-sectional view illustrating a step of bonding a third semiconductor chip die 170 on the semiconductor package 100 by flip-chip bonding, as one step of the series of steps of the method for fabricating the semiconductor package.

Referring to FIG. 14, the third semiconductor chip die 170 is mounted on the semiconductor package. Openings are formed in the second insulating layer 166 such that the bonding pads 165 are exposed. In an example embodiment, the openings may be formed using an exposure process or a CO₂ laser. Then, the third semiconductor chip die 170 is bonded to the bonding pads 165 of the back side printed circuit board (PCB) 160 using the connection members 175 by flip-chip bonding.

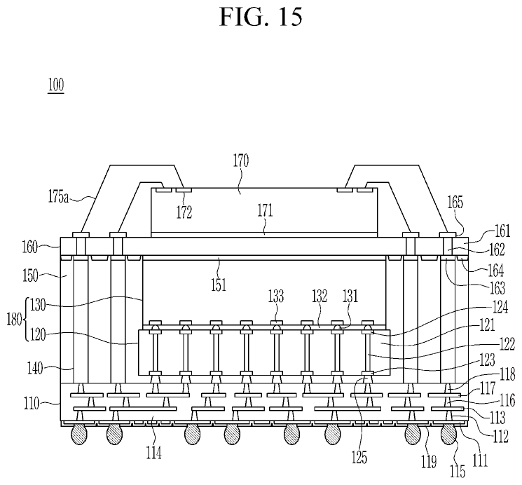

FIG. 15 is a cross-sectional view illustrating a step of bonding the third semiconductor chip die 170 on the semiconductor package 100 by wire bonding, as one step of the series of steps of the method for fabricating the semiconductor package.

Referring to FIG. 15, the third semiconductor chip die 170 is mounted on the semiconductor package. The third semiconductor chip die 170 is bonded to the back side printed circuit board (PCB) 160 by the die attach film (DAF) 151. The third semiconductor chip die 170 is electrically coupled with the back side printed circuit board (PCB) 160, using wires 175a connecting bonding pads 172 of the third semiconductor chip die 170 and the bonding pads 165 of the back side printed circuit board (PCB) 160.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor package comprising:
a redistribution layer;
a three-dimensional integrated circuit (3D IC) structure on the redistribution layer;
a plurality of conductive posts on the redistribution layer adjacent to the 3D IC structure;
a molding material on the redistribution layer and encapsulating the 3D IC structure and the plurality of conductive posts; and
a printed circuit board (PCB) on the molding material.

2. The semiconductor package of claim 1, wherein a coefficient of thermal expansion of the redistribution layer is greater than a coefficient of thermal expansion of the PCB.

3. The semiconductor package of claim 1, wherein a modulus of elasticity of the redistribution layer is smaller than a modulus of elasticity of the PCB.

4. The semiconductor package of claim 1, wherein the redistribution layer comprises:
a photosensitive dielectric (PID); and
a plurality of first conductive lines in the PID.

5. The semiconductor package of claim 1, wherein the PCB comprises:
a dielectric comprising glass fibers and epoxy; and
a plurality of second conductive lines in the dielectric.

6. The semiconductor package of claim 1, wherein the molding material comprises an epoxy molding compound (EMC).

7. The semiconductor package of claim 1, wherein a die attach film (DAF) is between the 3D IC structure and the PCB.

8. A semiconductor package comprising:
a redistribution layer;
a three-dimensional integrated circuit (3D IC) structure on the redistribution layer, the 3D IC structure comprising a first semiconductor chip die and a second semiconductor chip die below the first semiconductor chip die;
a plurality of conductive posts on the redistribution layer adjacent to the 3D IC structure;
a molding material on the redistribution layer and encapsulating the 3D IC structure and the plurality of conductive posts;
a printed circuit board (PCB) on the molding material; and
a third semiconductor chip die on the PCB,
wherein a lower surface of each conductive post of the plurality of conductive posts is on the redistribution layer and an upper surface of each conductive post of the plurality of conductive posts is below the PCB, and
wherein a die attach film (DAF) is between an upper surface of the first semiconductor chip die and the PCB and conductive connection members are between a lower surface of the second semiconductor chip die and the redistribution layer.

9. The semiconductor package of claim 8, wherein micro bumps are between a lower surface of the first semiconductor chip die and an upper surface of the second semiconductor chip die.

10. The semiconductor package of claim 8, wherein the first semiconductor chip die comprises a plurality of first bonding pads and a first insulating layer, and
wherein the second semiconductor chip die comprises a plurality of second bonding pads and a second insulating layer.

11. The semiconductor package of claim 10, wherein each first bonding pad of the plurality of first bonding pads is directly on each second bonding pad of the plurality of second bonding pads.

12. The semiconductor package of claim 10, wherein he plurality of first bonding pads and the plurality of second bonding pads comprise copper (Cu).

13. The semiconductor package of claim 10, wherein the first insulating layer is directly on the second insulating layer.

14. The semiconductor package of claim 10, wherein the first insulating layer and the second insulating layer comprise silicon oxide.

15. A method for fabricating a semiconductor package, comprising:
forming a plurality of conductive posts on a printed circuit board (PCB);
forming a three-dimensional integrated circuit (3D IC) structure on the PCB;
encapsulating the plurality of conductive posts and the 3D IC structure with a molding material;
forming a front side redistribution layer on the molding material; and
forming external connection terminals on the front side redistribution layer.

16. The method for fabricating the semiconductor package according to claim 15, wherein the forming the 3D IC structure on the PCB comprises mounting the 3D IC structure on the PCB.

17. The method for fabricating the semiconductor package according to claim 15, wherein the forming the 3D IC structure on the PCB comprises:
forming a first semiconductor chip die on the PCB, and
forming a second semiconductor chip die on the first semiconductor chip die.

18. The method for fabricating the semiconductor package according to claim 17, wherein in the forming the first semiconductor chip die on the PCB, the first semiconductor chip die is formed on the PCB by a die attach film (DAF).

19. The method for fabricating the semiconductor package according to claim 17, wherein the second semiconductor chip die is formed on the first semiconductor chip die based on hybrid bonding.

20. The method for fabricating the semiconductor package according to claim 15, further comprising:
planarizing upper surfaces of the plurality of conductive posts and an upper surface of the molding material by a chemical mechanical polishing (CMP) process or a mechanical grinding process, after the encapsulating the plurality of conductive posts and the 3D IC structure with the molding material.
